(19) United States
(12) Patent Application Publication
(10) Pub. No.: US 2025/0300473 A1
(43) Pub. Date: Sep. 25, 2025

(54) CHARGING CONTROL DEVICE, PORTABLE TERMINAL APPARATUS, CHARGING CONTROL METHOD, AND PROGRAM

(71) Applicant: SONY GROUP CORPORATION, TOKYO (JP)

(72) Inventors: TETSUYA MAKITA, TOKYO (JP); GO TANAKA, TOKYO (JP); KIMITAKA BENISE, TOKYO (JP); KUNIHARU SUZUKI, TOKYO (JP)

(21) Appl. No.: 18/862,871

(22) PCT Filed: Apr. 27, 2023
(86) PCT No.: PCT/JP2023/016584

§ 371 Date: Nov. 4, 2024

(30) Foreign Application Priority Data
May 10, 2022 (JP) 2022-077666

(51) Int. Cl. H02J 7/00

(52) U.S. Cl. CPC H02J 7/007; H02J 7/005

(57) ABSTRACT

In a charging control device 10, a processor 12 performs: calculating increase speed of storage degradation during a predetermined period on the basis of a first integrated amount and a second integrated amount, the first integrated amount being an integrated amount of the storage degradation of a battery 20 at a first point in time, the second integrated amount being the integrated amount of the storage degradation at a second point in time after the predetermined period has passed from the first point in time; predicting a third integrated amount that is the integrated amount of the storage degradation in a case where it is assumed that the calculated increase speed of the storage degradation is maintained until target operation time of the battery; predicting a second capacity retention rate on the basis of a first capacity retention rate, the third integrated amount, and the second integrated amount, the second capacity retention rate being a capacity retention rate of the battery at the target operation time, the first capacity retention rate being the capacity retention rate at the second point in time; and controlling the full-charging voltage value on the basis of the second capacity retention rate.

### FIELD

The present disclosure relates to a charging control device, a portable terminal apparatus, a charging control method, and a program.

### BACKGROUND

A battery mounted on a portable terminal apparatus expands due to repetitive charging in some cases, and as an amount of expansion of the battery increases, a charging capacity tends to decrease, and safety also tends to decrease. Furthermore, it is known that an amount of expansion that increases due to repetitive charging or discharging of the battery tends to increase in proportion to a magnitude of a full-charging voltage value of the battery. Accordingly, the portable terminal apparatus performs charging control to gradually reduce the full-charging voltage value of the battery in accordance with an increase in an integrated amount of damage that the battery suffers due to expansion of the battery (hereinafter referred to as “expansion damage” in some cases), in order to reduce an amount of expansion of the battery to a fixed level.

### CITATION LIST

### Patent Literature

Patent Literature 1: JP 2020-068607 A

### SUMMARY

### Technical Problem

However, a principal purpose of charging control based on an integrated amount of expansion damage is to avoid expansion of a battery, and therefore even if charging control based on an integrated amount of expansion damage is performed, it is difficult to avoid storage degradation of the battery.

Accordingly, the present disclosure proposes a technique that can avoid the storage degradation of the battery.

### Solution to Problem

A charging control device of the present disclosure includes a charging circuit and a processor. The charging circuit charges a battery until a voltage value of the battery reaches a full-charging voltage value. The processor calculates increase speed of storage degradation during a predetermined period on a basis of a first integrated amount and a second integrated amount, the first integrated amount being an integrated amount of the storage degradation of the battery at a first point in time, the second integrated amount being the integrated amount of the storage degradation at a second point in time after the predetermined period has passed from the first point in time. The processor predicts a third integrated amount that is the integrated amount of the storage degradation in a case where it is assumed that the increase speed is maintained until target operation time of the battery. The processor predicts a second capacity retention rate on the basis of a first capacity retention rate, the third integrated amount, and the second integrated amount, the second capacity retention rate being a capacity retention rate of the battery at the target operation time, the first capacity retention rate being the capacity retention rate at the second point in time. And the processor controls the full-charging voltage value on the basis of the second capacity retention rate.

### BRIEF DESCRIPTION OF DRAWINGS

FIG. 1 is a diagram illustrating a configuration example of a portable terminal apparatus according to a first embodiment of the present disclosure.

FIG. 2 is a flowchart illustrating an example of a processing procedure of a charging control device according to the first embodiment of the present disclosure.

FIG. 3 is a diagram for explaining an operation example of the charging control device according to the first embodiment of the present disclosure.

FIG. 4 is a diagram for explaining an operation example of the charging control device according to the first embodiment of the present disclosure.

FIG. 5 is a diagram for explaining an operation example of the charging control device according to the first embodiment of the present disclosure.

FIG. 6 is a diagram illustrating an example of screen display according to a second embodiment of the present disclosure.

FIG. 7 is a diagram illustrating an example of screen display according to the second embodiment of the present disclosure.

### DESCRIPTION OF EMBODIMENTS

Embodiments of the present disclosure are described below with reference to the drawings. Note that in the embodiments described below, the same portion or the same process is denoted by the same reference sign, and therefore a duplicate description is omitted in some cases.

Furthermore, the technique of the present disclosure is described according to the item order described below.

[First Embodiment]
<Configuration of Portable Terminal Apparatus>
<Processing Procedure of Charging Control Device>
<Operation of Charging Control Device>
   <First Operation Example>
   <Second Operation Example>
   <Third Operation Example>

[Second Embodiment]

[Third Embodiment]

[Advantageous Effects of Technique of Disclosure]

### First Embodiment

### <Configuration of Portable Terminal Apparatus>

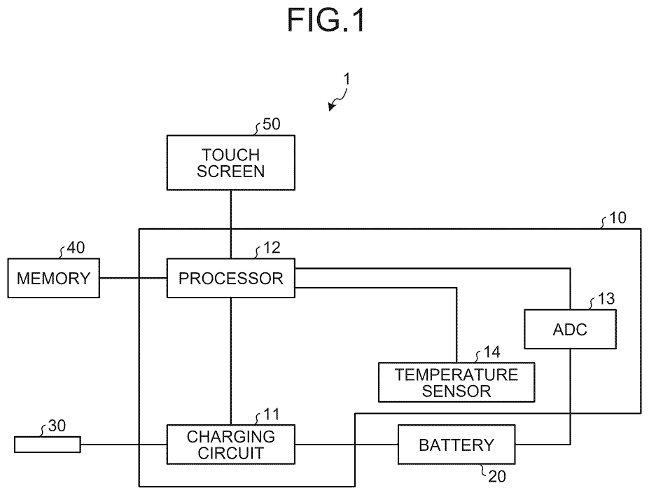

FIG. 1 is a diagram illustrating a configuration example of a portable terminal apparatus according to a first embodiment of the present disclosure. In FIG. 1, a portable terminal apparatus 1 includes a charging control device 10, a battery 20, a charging terminal 30, a memory 40, and a touch screen 50. The charging control device 10 includes a charging circuit 11, a processor 12, an analog-to-digital converter (ADC) 13, and a temperature sensor 14. Note that the battery 20 may include the temperature sensor 14.

Examples of the portable terminal apparatus 1 include a smart device such as a smartphone or a tablet, a laptop type personal computer, a wireless earphone, a wireless headphone, a portable speaker, and the like. Examples of the processor 12 include a central processing unit (CPU), a digital signal processor (DSP), and a field programmable gate array (FPGA). Examples of the memory 40 include a random access memory (RAM), a read only memory (ROM), and a flash memory. An example of the battery 20 is a lithium-ion battery.

When the battery 20 is charged, a commercial power supply is connected to the portable terminal apparatus 1 via the charging terminal 30, and the battery 20 is charged by the commercial power supply. The commercial power supply is connected to the charging terminal 30 via an AC adapter (not illustrated), and the AC adapter steps down the commercial power supply of, for example, a 100-V alternating current to convert the commercial power supply into a DC power supply of 5 V.

A voltage of the battery 20 is input to the ADC 13. The ADC 13 detects a voltage value of the battery 20 (hereinafter referred to as a “battery voltage value” in some cases), converts a detected analog voltage value into a digital voltage value, and outputs a digital battery voltage value after conversion to the processor 12.

The processor 12 controls the charging circuit 11 to control charging the battery 20. The processor 12 causes the charging circuit 11 to start to charge the battery 20 with connection of the commercial power supply to the charging terminal 30 via the AC adapter as a trigger. Furthermore, when the charging circuit 11 charges the battery 20, the processor 12 causes the charging circuit 11 to charge the battery 20 until the battery voltage value reaches a full-charging voltage value.

The processor 12 also calculates an integrated amount of storage degradation of the battery 20 (hereinafter referred to as a “storage degradation integrated amount” in some cases), and controls the full-charging voltage value on the basis of the calculated storage degradation integrated amount.

The charging circuit 11 uses the direct power supply that is supplied from the AC adapter, and charges the battery 20 until the battery voltage value reaches the full-charging voltage value, under the control of the processor 12.

The temperature sensor 14 detects the temperature of the battery 20 (hereinafter referred to as “battery temperature” in some cases), and outputs the detected battery temperature to the processor 12.

### <Processing Procedure of Charging Control Device>

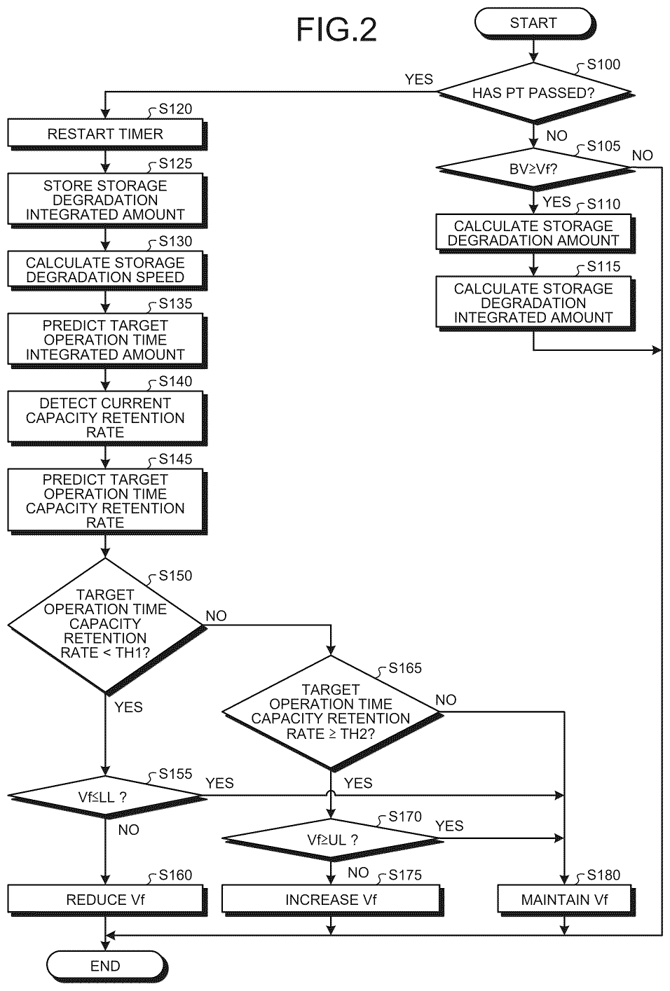

FIG. 2 is a flowchart illustrating an example of a processing procedure of a charging control device according to the first embodiment of the present disclosure. The flowchart illustrated in FIG. 2 starts each unit time (for example, 10-second intervals).

In FIG. 2, in Step S100, the processor 12 determines whether a repeat timer included in the processor 12 has expired. A predetermined period PT [day] has been set in advance for the repeat timer, and therefore the processor 12 determines whether the repeat timer has expired to determine whether the predetermined period PT has passed from a point in time of previous restart of the repeat timer. As an example of the predetermined period PT, 10 days have been set in advance for the repeat timer. When the predetermined period PT has not passed (Step S100: No), the processing moves on to Step S105, and when the predetermined period PT has passed (Step S100: Yes), the processing moves on to Step S120.

In Step S105, the processor 12 determines whether a battery voltage value BV [V] has reached a full-charging voltage value Vf [V]. When the battery voltage value BV has reached the full-charging voltage value Vf (Step S105: Yes), the processing moves on to Step S110, and when the battery voltage value BV has not reached the full-charging voltage value Vf (Step S105: No), the processing procedure illustrated in FIG. 2 terminates.

In Step S110, the processor 12 calculates a storage degradation amount SD [%] per unit time (for example, 10 seconds) on the basis of the full-charging voltage value Vf and battery temperature TP [° C.]. Here, in a case where the battery temperature TP is constant, as the full-charging voltage value Vf increases, the increase speed of the storage degradation integrated amount (hereinafter referred to as “storage degradation speed” in some cases) increases. Furthermore, in a case where the full-charging voltage value Vf is constant, as the battery temperature TP increases, the storage degradation speed increases. Accordingly, the processor 12 calculates the storage degradation amount SD per unit time according to Formula (1). The function f described as Formula (1) is derived on the basis of a relationship among the full-charging voltage value Vf, the battery temperature TP, and the storage degradation speed with the full-charging voltage value Vf and the battery temperature TP as variables, by using, for example, multiple regression analysis.

$$SD = f ( Vf , TP ) \qquad ( 1 )$$

Next, in Step S115, the processor 12 adds the storage degradation amount SD calculated in current Step S110 to a storage degradation integrated amount DI [%] calculated in previous Step S115 to calculate a current storage degradation integrated amount DI. After the process of Step S115, the processing procedure illustrated in FIG. 2 terminates.

On the other hand, in Step S120, the processor 12 restarts the repeat timer.

Next, in Step S125, the processor 12 stores a storage degradation integrated amount DI at a current point in time in the memory 40. Therefore, a storage degradation integrated amount DI calculated in each predetermined period PT is sequentially stored in the memory 40 in accordance with an increase in the operation time of the battery 20.

Next, in Step S130, the processor 12 calculates storage degradation speed DS.

Next, in Step S135, the processor 12 predicts a storage degradation integrated amount at a point in time when the operation time BOT of the battery 20 reaches target operation time TOT [day] (hereinafter referred to as a “target operation time integrated amount” in some cases) on the basis of the storage degradation speed DS calculated in Step S130. The processor 12 predicts, as the target operation time integrated amount, a storage degradation integrated amount at the target operation time TOT in a case where it is assumed that the storage degradation speed DS calculated in Step S130 is maintained until the target operation time TOT.

Next, in Step S140, the processor 12 detects a capacity retention rate at a current point in time of the battery 20 (hereinafter referred to as a “current capacity retention rate” in some cases) [%] on the basis of a capacity [mAh] of the battery 20 that can be measured from an amount of electric charges flowing into the battery 20 from the charging circuit 11 at the time of charging the battery 20. For example, the processor 12 detects, as the current capacity retention rate, a ratio of a capacity of the battery 20 at a current point in time to a capacity of the battery 20 at the time of start of use.

Next, in Step S145, the processor 12 predicts a capacity retention rate of the battery 20 at a point in time when the operation time BOT of the battery 20 reaches the target operation time TOT (hereinafter referred to as a “target operation time capacity retention rate” in some cases) [%] on the basis of the target operation time integrated amount predicted in Step S135.

Next, in Step S150, the processor 12 determines whether the target operation time capacity retention rate predicted in Step S145 is less than a threshold TH1. When the target operation time capacity retention rate is less than the threshold TH1 (Step S150: Yes), the processing moves on to Step S155, and when the target operation time capacity retention rate is greater than or equal to the threshold TH1 (Step S150: No), the processing moves on to Step S165.

In Step S155, the processor 12 determines whether the full-charging voltage value Vf is less than or equal to a lower limit value LL. When the full-charging voltage value Vf is greater than the lower limit value LL (Step S155: No), the processing moves on to Step S160, and when the full-charging voltage value Vf is less than or equal to the lower limit value LL (Step S155: Yes), the processing moves on to Step S180. The lower limit value LL may be a fixed value, or may be dynamically changed according to the operation time BOT of the battery 20 or a degradation condition of the battery 20.

In Step S160, the processor 12 reduces the full-charging voltage value Vf by a predetermined value. After the process of Step S160, the processing procedure illustrated in FIG. 2 terminates.

On the other hand, in Step S165, the processor 12 determines whether the target operation time capacity retention rate predicted in Step S145 is greater than or equal to a threshold TH2, which is greater than the threshold TH1 by a predetermined value. When the target operation time capacity retention rate is greater than or equal to the threshold TH2 (Step S165: Yes), the processing moves on to Step S170, and when the target operation time capacity retention rate is less than the threshold TH2 (Step S165: No), the processing moves on to Step S180.

In Step S170, the processor 12 determines whether the full-charging voltage value Vf is greater than or equal to an upper limit value UL. When the full-charging voltage value Vf is less than the upper limit value UL (Step S170: No), the processing moves on to Step S175, and when the full-charging voltage value Vf is greater than or equal to the upper limit value UL (Step S170: Yes), the processing moves on to Step S180. The upper limit value UL may be a fixed value, or may be dynamically changed according to the operation time BOT of the battery 20 or a degradation condition of the battery 20.

In Step S175, the processor 12 increases the full-charging voltage value Vf by a predetermined value. After the process of Step S175, the processing procedure illustrated in FIG. 2 terminates.

On the other hand, in Step S180, the processor 12 maintains the full-charging voltage value Vf with no change. After the process of Step S180, the processing procedure illustrated in FIG. 2 terminates.

### <Operation of Charging Control Device>

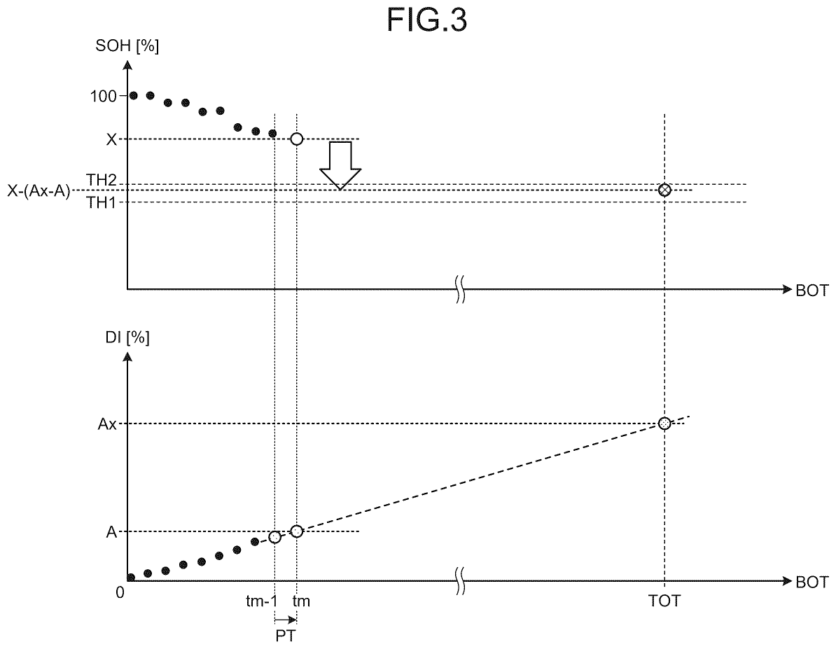

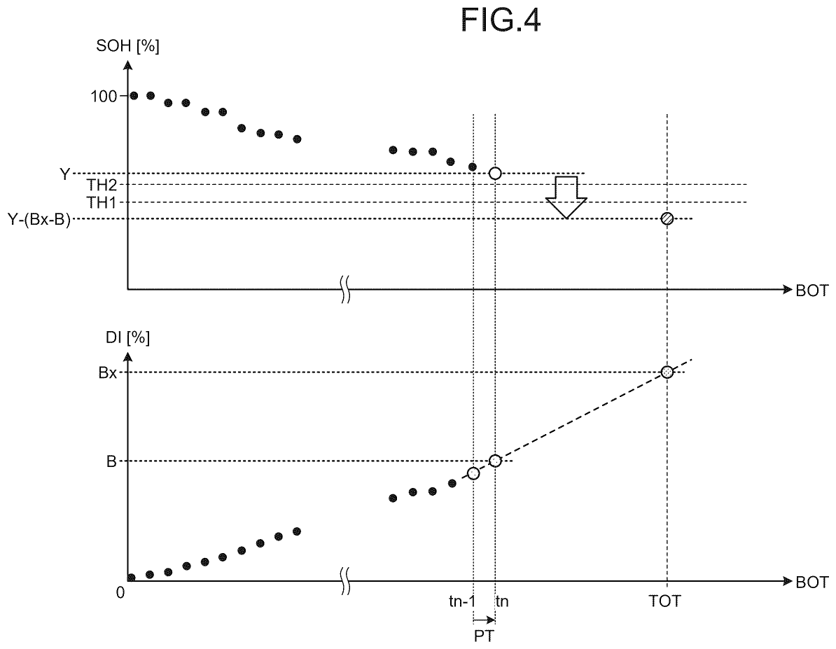

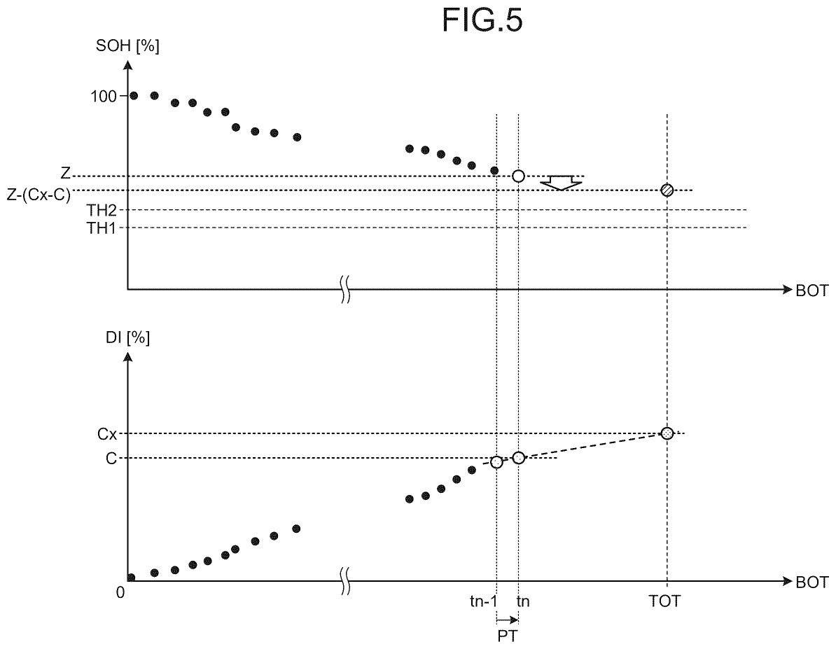

FIGS. 3, 4, and 5 are diagrams for explaining operation examples of the charging control device according to the first embodiment of the present disclosure. FIG. 3 illustrates an operation example in a case where the full-charging voltage value Vf is maintained with no change (a first operation example), FIG. 4 illustrates an operation example in a case where the full-charging voltage value Vf is reduced (a second operation example), and FIG. 5 illustrates an operation example in a case where the full-charging voltage value Vf is increased (a third operation example). The first operation example, the second operation example, and the third operation example are separately described below. In the description below, the target operation time TOT [day] of the battery 20 is set to, for example, three years (=1095 days). Furthermore, in the description below, the threshold TH1 is set to, for example, 80%, and the threshold TH2 is set to, for example, 81%, which is greater than the threshold TH1 by 1%.

### First Operation Example

In FIG. 3, the processor 12 calculates storage degradation speed DS according to Formula (2) at a point in time tₘ [day] when a predetermined period PT has passed from a point in time tₘ₋₁ [day] of previous restart of the repeat timer with an operation time BOT of 0 [day] as a starting point (Step S130). In Formula (2), “Aₘ₋₁” is a storage degradation integrated amount DI at the point in time tₘ₋₁, and “A” is a storage degradation integrated amount DI at the point in time tₘ.

$$DS = ( A - {A}_{m - 1} ) / PT \qquad ( 2 )$$

Next, the processor 12 predicts a target operation time integrated amount Ax according to Formula (3) (Step S135).

$$Ax = ( ( ( A - {A}_{m - 1} ) / PT ) \times ( TOT - {t}_{m} ) ) + A \qquad ( 3 )$$

Next, the processor 12 detects a current capacity retention rate X at the point in time tₘ (Step S140).

Next, the processor 12 predicts a target operation time capacity retention rate Xx according to Formula (4) (Step S145).

$$Xx = X - ( Ax - A ) \qquad ( 4 )$$

Next, the predicted target operation time capacity retention rate Xx is greater than or equal to the threshold TH1, and is less than the threshold TH2 (Step S150: No, Step S165: No), and therefore the processor 12 maintains the full-charging voltage value Vf with no change (Step S180).

### Second Operation Example

In FIG. 4, the processor 12 calculates storage degradation speed DS according to Formula (5) at a point in time tₙ [day] when a predetermined period PT has passed from a point in time tₙ₋₁ [day] of previous restart of the repeat timer with an operation time BOT of 0 [day] as a starting point (Step S130). In Formula (5), “Bₙ₋₁” is a storage degradation integrated amount DI at the point in time tₙ₋₁, and “B” is a storage degradation integrated amount DI at the point in time tₙ.

$$DS = ( B - {B}_{n - 1} ) / PT \qquad ( 5 )$$

Next, the processor 12 predicts a target operation time integrated amount Bx according to Formula (6) (Step S135).

$$Bx = ( ( ( B - {B}_{n - 1} ) / PT ) \times ( TOT - {t}_{n} ) ) + B \qquad ( 6 )$$

Next, the processor 12 detects a current capacity retention rate Y at the point in time tₙ (Step S140).

Next, the processor 12 predicts a target operation time capacity retention rate Yx according to Formula (7) (Step S145).

$$Yx = Y - ( Bx - B ) \qquad ( 7 )$$

Next, the predicted target operation time capacity retention rate Yx is less than the threshold TH1 (Step S150: Yes), and therefore when the full-charging voltage value Vf is greater than the lower limit value LL (Step S155: No), the processor 12 reduces the full-charging voltage value Vf by a predetermined value (Step S160).

### Third Operation Example

In FIG. 5, the processor 12 calculates storage degradation speed DS according to Formula (8) at the point in time tₙ [day] when a predetermined period PT has passed from the point in time tₙ₋₁ [day] of previous restart of the repeat timer with an operation time BOT of 0 [day] as a starting point (Step S130). In Formula (8), “Cₙ₋₁” is a storage degradation integrated amount DI at the point in time tₙ₋₁, and “C” is a storage degradation integrated amount DI at the point in time tₙ.

$$DS = ( C - {C}_{n - 1} ) / PT \qquad ( 8 )$$

Next, the processor 12 predicts a target operation time integrated amount Cx according to Formula (9) (Step $135).

$$Cx = ( ( ( C - {C}_{n - 1} ) / PT ) \times ( TOT - {t}_{n} ) ) + C \qquad ( 9 )$$

Next, the processor 12 detects a current capacity retention rate Z at the point in time tₙ (Step S140).

Next, the processor 12 predicts a target operation time capacity retention rate Zx according to Formula (10) (Step S145).

$$Zx = Z - ( Cx - C ) \qquad ( 10 )$$

Next, the predicted target operation time capacity retention rate Zx is greater than or equal to the threshold TH2 (Step S165: Yes), and therefore when the full-charging voltage value Vf is less than the upper limit value UL (Step S170: No), the processor 12 increases the full-charging voltage value Vf by a predetermined value (Step S175).

The first embodiment has been described above.

### Second Embodiment

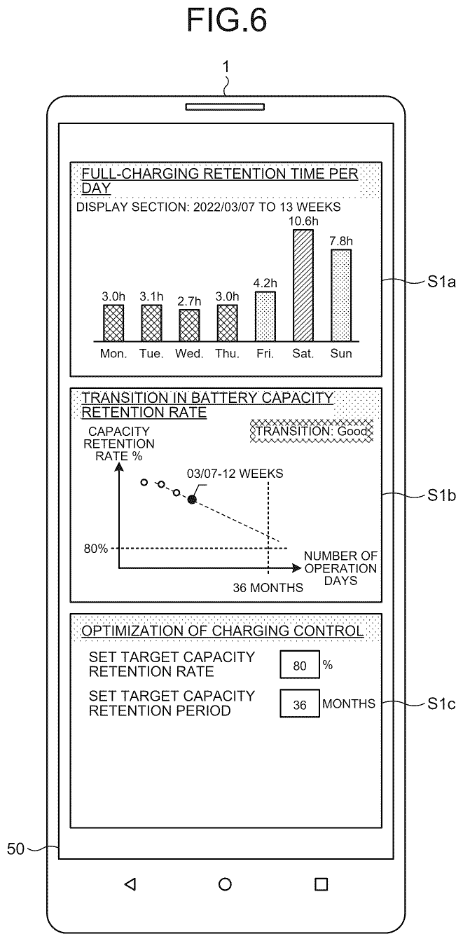

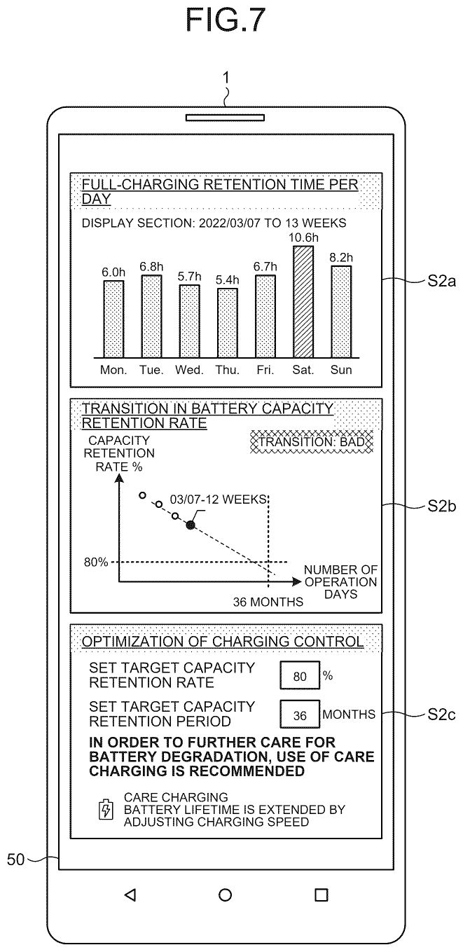

FIGS. 6 and 7 are diagrams illustrating an example of screen display according to a second embodiment of the present disclosure. FIG. 6 illustrates an example of screen display on the touch screen 50 of the portable terminal apparatus 1 that includes the battery 20 having low storage degradation speed, and FIG. 7 illustrates an example of screen display on the touch screen 50 of the portable terminal apparatus 1 that includes the battery 20 having high storage degradation speed.

As illustrated in FIGS. 6 and 7, the processor 12 causes the touch screen 50 to display screens S1a and S2a indicating the time during which the battery voltage value BV has been retained at the full-charging voltage value Vf (hereinafter referred to as “full-charging retention time” in some cases). On the screens S1a and S2a, the full-charging retention time for each day of the week or each date of one week is indicated in a bar graph form, a full-charging retention time that is less than four hours is indicated by a green bar, a full-charging retention time that is greater than or equal to four hours and is less than nine hours is indicated by an orange bar, and a full-charging retention time that is greater than or equal to nine hours is indicated by a red bar. Furthermore, for example, the full-charging retention time for each day of the week or each date may be indicated in a line graph form.

Furthermore, the processor 12 causes the touch screen 50 to display screens S1b and S2b indicating a transition in the capacity retention rate of the battery 20. The screens S1b and S2b indicate, for example, a target capacity retention rate (for example, 80%) that corresponds to the threshold TH1, and a target capacity retention period (for example, 36 months) that corresponds to the target operation time TOT. Furthermore, when the target operation time capacity retention rate is greater than or equal to the target capacity retention rate, it is displayed that a transition in the capacity retention rate is satisfactory (TRANSITION: Good), as illustrated as the screen S1b. On the other hand, when the target operation time capacity retention rate is less than the target capacity retention rate, it is displayed that a transition in the capacity retention rate is unsatisfactory (TRANSITION: BAD), as illustrated as the screen S2b.

Furthermore, the processor 12 causes the touch screen 50 to display screens S1c and S2c on which an arbitrary target capacity retention rate can be set, and an arbitrary target capacity retention period can be set. A user of the portable terminal apparatus 1 inputs an arbitrary target capacity retention rate and an arbitrary capacity retention period onto the screen S1c and S2c, and therefore the processor 12 sets the input target capacity retention rate as the threshold TH1, and sets the input target capacity retention period as the target operation time TOT. Furthermore, the processor 12 sets, as the threshold TH2, a value that is greater than the input target capacity retention rate by a predetermined value.

The second embodiment has been described above.

### Third Embodiment

The respective processes described above that are performed by the processor 12 may be implemented by causing the processor 12 to execute a program that corresponds to the respective processes. For example, the program that corresponds to the respective processes described above may be stored in the memory 40, and the processor 12 may read the program from the memory 40, and may execute the program. Furthermore, the program may be stored in a program server that is connected to the portable terminal apparatus 1 via an arbitrary network, may be downloaded into the portable terminal apparatus 1 from the program server, and may be executed, or the program may be stored in a recording medium that is readable by the portable terminal apparatus 1, may be read from the recording medium, and may be executed. The recording medium that is readable by the portable terminal apparatus 1 includes a portable storage medium such as a memory card, a USB memory, an SD card, a flexible disk, a magneto-optical disk, a CD-ROM, a DVD, or a Blu-ray (registered trademark) disk. Furthermore, the program is described in an arbitrary language or according to an arbitrary description method, and a format of a source cord, a binary cord, or the like is not particularly limited. Furthermore, the program is not necessarily limited to a program having a single configuration, and includes a program that is configured in a distributed manner as a plurality of modules or a plurality of libraries or a program that achieves functions in collaboration with a separate program represented by OS.

The third embodiment has been described above.

### Advantageous Effects of Technique of Disclosure

As described above, a charging control device of the present disclosure (the charging control device 10 according to the embodiment) includes a charging circuit (the charging circuit 11 according to the embodiment) and a processor (the processor 12 according to the embodiment). The charging circuit charges a battery (the battery 20 according to the embodiment) until a voltage value of the battery reaches a full-charging voltage value. The processor calculates increase speed of storage degradation (the storage degradation speed DS according to the embodiment) during a predetermined period (the predetermined period PT according to the embodiment) on the basis of a first integrated amount (the storage degradation integrated amount Aₘ₋₁, Bₙ₋₁, or Cₙ₋₁ according to the embodiment) and a second integrated amount (the storage degradation integrated amount A, B, or C according to the embodiment). The first integrated amount is an integrated amount of the storage degradation of the battery at a first point in time (the point in time tₘ₋₁ or tₙ₋₁ according to the embodiment), and the second integrated amount is the integrated amount of the storage degradation at a second point in time (the point in time tₘ or tₙ according to the embodiment) after the predetermined period has passed from the first point in time. Furthermore, the processor predicts a third integrated amount (the target operation time integrated amount according to the embodiment) that is the integrated amount of the storage degradation in a case where it is assumed that the calculated increase speed of the storage degradation is maintained until target operation time (the target operation time TOT according to the embodiment) of the battery. Moreover, the processor predicts a second capacity retention rate (the target operation time capacity retention rate according to the embodiment) on the basis of a first capacity retention rate (the current capacity retention rate according to the embodiment), the third integrated amount, and the second integrated amount, and controls the full-charging voltage value on the basis of the second capacity retention rate. The second capacity retention rate is a capacity retention rate of the battery at the target operation time, and the first capacity retention rate is the capacity retention rate at the second point in time.

For example, the processor reduces the full-charging voltage value when the second capacity retention rate is less than a first threshold (the threshold TH1 according to the embodiment). As another example, the processor increases the full-charging voltage value when the second capacity retention rate is greater than or equal to a second threshold (the threshold TH2 according to the embodiment) that is greater than the first threshold by a predetermined value. As yet another example, the processor does not change the full-charging voltage value when the second capacity retention rate is greater than or equal to the first threshold, and is less than the second threshold.

This can avoid the storage degradation of the battery. Furthermore, the full-charging voltage value is adjusted according to the magnitude of the increase speed of the storage degradation. Therefore, when the pace of decrease in the capacity retention rate due to the storage degradation is fast, the full-charging voltage value can be reduced, and when the pace of decrease in the capacity retention rate due to the storage degradation is slow, the full-charging voltage value can be increased. Therefore, the balance between avoidance of the storage degradation and the available time of the battery that has been charged to the full-charging voltage value can be kept according to a use state of the battery, and this can maximize a lifelong capacity of the battery.

Furthermore, a portable terminal apparatus of the present disclosure (the portable terminal apparatus 1 according to the embodiment) includes the charging control device and a touch screen (the touch screen 50 according to the embodiment), and the processor causes the touch screen to display the time during which the voltage value of the battery has been retained at the full-charging voltage value.

This visualizes the time during which the voltage value of the battery has been retained at the full-charging voltage value, and therefore a user of the portable terminal apparatus can be given an opportunity to reconsider a method for charging the battery from the point of view of avoidance of the storage degradation.

Furthermore, the processor causes the touch screen to display a transition in the capacity retention rate of the battery.

This visualizes a transition in the capacity retention rate of the battery, and therefore the user of the portable terminal apparatus can be given an opportunity to reconsider a method for charging the battery from the point of view of a reduction in the pace of decrease in the capacity retention rate.

Furthermore, the processor sets the target operation time and the first threshold in accordance with an input value of the touch screen.

This enables the user of the portable terminal apparatus to freely change the target operation time and the first threshold, and therefore charging control that meets the user's needs of use can be achieved.

Note that the advantageous effects described herein are only illustrative, and are not restrictive, and other advantageous effects may be exhibited.

Furthermore, the technique of the disclosure can also employ the configuration described below.

(1)

A charging control device comprising:
a charging circuit that charges a battery until a voltage value of the battery reaches a full-charging voltage value; and
a processor that performs:
calculating increase speed of storage degradation during a predetermined period on a basis of a first integrated amount and a second integrated amount, the first integrated amount being an integrated amount of the storage degradation of the battery at a first point in time, the second integrated amount being the integrated amount of the storage degradation at a second point in time after the predetermined period has passed from the first point in time;
predicting a third integrated amount that is the integrated amount of the storage degradation in a case where it is assumed that the increase speed is maintained until target operation time of the battery;
predicting a second capacity retention rate on the basis of a first capacity retention rate, the third integrated amount, and the second integrated amount, the second capacity retention rate being a capacity retention rate of the battery at the target operation time, the first capacity retention rate being the capacity retention rate at the second point in time; and
controlling the full-charging voltage value on the basis of the second capacity retention rate.

(2)

The charging control device according to (1), wherein
the processor reduces the full-charging voltage value when the second capacity retention rate is less than a first threshold.

(3)

The charging control device according to (2), wherein
the processor increases the full-charging voltage value when the second capacity retention rate is greater than or equal to a second threshold that is greater than the first threshold by a predetermined value.

(4)

The charging control device according to (3), wherein
the processor does not change the full-charging voltage value when the second capacity retention rate is greater than or equal to the first threshold, and is less than the second threshold.

(5)

A portable terminal apparatus comprising:
the charging control device according to (1); and
a touch screen.

(6)

The portable terminal apparatus according to (5), wherein
the processor causes the touch screen to display a time during which the voltage value of the battery has been retained at the full-charging voltage value.

(7)

The portable terminal apparatus according to (6) described above, in which
the processor causes the touch screen to display the time during which the voltage value of the battery has been retained at the full-charging voltage value in a form of a graph for each day of the week or each date.

(8)

The portable terminal apparatus according to (5), wherein
the processor causes the touch screen to display a transition in the capacity retention rate of the battery.

(9)

The portable terminal apparatus according to (8) described above, in which
the processor causes the touch screen to display whether the transition in the capacity retention rate is satisfactory.

(10)

The portable terminal apparatus according to (5), wherein
the processor performs:
reducing the full-charging voltage value when the second capacity retention rate is less than a first threshold; and
setting the target operation time and the first threshold in accordance with an input value of the touch screen.

(11)

The portable terminal apparatus according to (10) described above, in which
the processor causes the touch screen to display a screen that enables the target operation time and the first threshold to be arbitrarily set.

(12)

A charging control method that is performed on a battery that is charged until a voltage value reaches a full-charging voltage value, the charging control method comprising:
calculating increase speed of storage degradation during a predetermined period on a basis of a first integrated amount and a second integrated amount, the first integrated amount being an integrated amount of the storage degradation of the battery at a first point in time, the second integrated amount being the integrated amount of the storage degradation at a second point in time after the predetermined period has passed from the first point in time;
predicting a third integrated amount that is the integrated amount of the storage degradation in a case where it is assumed that the increase speed is maintained until target operation time of the battery;
predicting a second capacity retention rate on the basis of a first capacity retention rate and the third integrated amount, the second capacity retention rate being a capacity retention rate of the battery at the target operation time, the first capacity retention rate being the capacity retention rate at the second point in time; and
controlling the full-charging voltage value on the basis of the second capacity retention rate.

(13)

A program for causing a processor to perform charging control on a battery that is charged until a voltage value reaches a full-charging voltage value, the program for causing the processor to execute a process comprising:
calculating increase speed of storage degradation during a predetermined period on a basis of a first integrated amount and a second integrated amount, the first integrated amount being an integrated amount of the storage degradation of the battery at a first point in time, the second integrated amount being the integrated amount of the storage degradation at a second point in time after the predetermined period has passed from the first point in time;
predicting a third integrated amount that is the integrated amount of the storage degradation in a case where it is assumed that the increase speed is maintained until target operation time of the battery;
predicting a second capacity retention rate on the basis of a first capacity retention rate and the third integrated amount, the second capacity retention rate being a capacity retention rate of the battery at the target operation time, the first capacity retention rate being the capacity retention rate at the second point in time; and
controlling the full-charging voltage value on the basis of the second capacity retention rate.

### REFERENCE SIGNS LIST

1 PORTABLE TERMINAL APPARATUS
10 CHARGING CONTROL DEVICE
11 CHARGING CIRCUIT
12 PROCESSOR
13 ADC
14 TEMPERATURE SENSOR
20 BATTERY
30 CHARGING TERMINAL
40 MEMORY
50 TOUCH SCREEN

1. A charging control device comprising:
a charging circuit that charges a battery until a voltage value of the battery reaches a full-charging voltage value; and
a processor that performs:
calculating increase speed of storage degradation during a predetermined period on a basis of a first integrated amount and a second integrated amount, the first integrated amount being an integrated amount of the storage degradation of the battery at a first point in time, the second integrated amount being the integrated amount of the storage degradation at a second point in time after the predetermined period has passed from the first point in time;
predicting a third integrated amount that is the integrated amount of the storage degradation in a case where it is assumed that the increase speed is maintained until target operation time of the battery;
predicting a second capacity retention rate on the basis of a first capacity retention rate, the third integrated amount, and the second integrated amount, the second capacity retention rate being a capacity retention rate of the battery at the target operation time, the first capacity retention rate being the capacity retention rate at the second point in time; and
controlling the full-charging voltage value on the basis of the second capacity retention rate.

2. The charging control device according to claim 1, wherein
the processor reduces the full-charging voltage value when the second capacity retention rate is less than a first threshold.

3. The charging control device according to claim 2, wherein
the processor increases the full-charging voltage value when the second capacity retention rate is greater than or equal to a second threshold that is greater than the first threshold by a predetermined value.

4. The charging control device according to claim 3, wherein
the processor does not change the full-charging voltage value when the second capacity retention rate is greater than or equal to the first threshold, and is less than the second threshold.

5. A portable terminal apparatus comprising:
the charging control device according to claim 1; and
a touch screen.

6. The portable terminal apparatus according to claim 5, wherein
the processor causes the touch screen to display a time during which the voltage value of the battery has been retained at the full-charging voltage value.

7. The portable terminal apparatus according to claim 5, wherein
the processor causes the touch screen to display a transition in the capacity retention rate of the battery.

8. The portable terminal apparatus according to claim 5, wherein
the processor performs:
reducing the full-charging voltage value when the second capacity retention rate is less than a first threshold; and
setting the target operation time and the first threshold in accordance with an input value of the touch screen.

9. A charging control method that is performed on a battery that is charged until a voltage value reaches a full-charging voltage value, the charging control method comprising:
calculating increase speed of storage degradation during a predetermined period on a basis of a first integrated amount and a second integrated amount, the first integrated amount being an integrated amount of the storage degradation of the battery at a first point in time, the second integrated amount being the integrated amount of the storage degradation at a second point in time after the predetermined period has passed from the first point in time;
predicting a third integrated amount that is the integrated amount of the storage degradation in a case where it is assumed that the increase speed is maintained until target operation time of the battery;
predicting a second capacity retention rate on the basis of a first capacity retention rate and the third integrated amount, the second capacity retention rate being a capacity retention rate of the battery at the target operation time, the first capacity retention rate being the capacity retention rate at the second point in time; and
controlling the full-charging voltage value on the basis of the second capacity retention rate.

10. A program for causing a processor to perform charging control on a battery that is charged until a voltage value reaches a full-charging voltage value, the program for causing the processor to execute a process comprising:
calculating increase speed of storage degradation during a predetermined period on a basis of a first integrated amount and a second integrated amount, the first integrated amount being an integrated amount of the storage degradation of the battery at a first point in time, the second integrated amount being the integrated amount of the storage degradation at a second point in time after the predetermined period has passed from the first point in time;
predicting a third integrated amount that is the integrated amount of the storage degradation in a case where it is assumed that the increase speed is maintained until target operation time of the battery;
predicting a second capacity retention rate on the basis of a first capacity retention rate and the third integrated amount, the second capacity retention rate being a capacity retention rate of the battery at the target operation time, the first capacity retention rate being the capacity retention rate at the second point in time; and
controlling the full-charging voltage value on the basis of the second capacity retention rate.
